(19) United States
(12) Patent Application Publication
(10) Pub. No.: US 2026/0013041 A1
(43) Pub. Date: Jan. 8, 2026

(54) MULTI-LAYER CIRCUIT BOARD FOR CLOSELY PACKED LIGHT-EMITTING DIODE (LED) ARRAYS AND METHOD OF MANUFACTURE

(71) Applicant: LUMILEDS LLC, San Jose, CA (US)

(72) Inventors: Frans Hubert Konijn, Huizen (NL); Pieter Johannes Quintus van Voorst Vader, Son (NL)

(73) Assignee: LUMILEDS LLC, San Jose, CA (US)

(21) Appl. No.: 18/880,210

(22) PCT Filed: Jun. 30, 2023
(86) PCT No.: PCT/US2023/026675

§ 371 Date: Dec. 30, 2024

Related U.S. Application Data
(60) Provisional application No. 63/357,404, filed on Jun. 30, 2022.

(51) Int. Cl. H05K 1/02; H05K 1/11

(52) U.S. Cl. CPC H05K 1/0298; H05K 1/0203; H05K 1/111; H05K 1/115; H05K 2201/10106

(57) ABSTRACT

Multi-layer circuit boards and methods of manufacture are described herein. A multi-layer circuit board includes a top layer and a bottom layer. The top layer includes an array of metal sections that are electrically insulated from one another. The metal sections at a periphery of the array extend to an outer periphery of the multi-layer circuit board. The innermost metal sections in the array are electrically and thermally coupled to the bottom layer by vias formed through all of the top layer and any layers between the top layer and the bottom layer.

### CROSS-REFERENCE TO RELATED APPLICATIONS

This application claims the benefit of U.S. Provisional Application No. 63/357,404, filed Jun. 30, 2022, the contents of which are incorporated herein by reference.

### BACKGROUND

Arrays of LED emitters (e.g., a 7×7 array), as opposed to a single LED, for example, may be used, among other things, to create better illumination control for lighting applications. However, for optical design reasons (e.g., small source size), miniaturization reasons, or other reasons, the overall size of the light-source, which may include one or more arrays of LED emitters, may need to be minimized. Accordingly, some light sources may include a composite of multiple, closely packed LEDs or a single component made up of separated LED emitter zones that are individually addressable, such as in a square or rectangular formation.

### SUMMARY

Multi-layer circuit boards and methods of manufacture are described herein. A multi-layer circuit board includes a top layer and a bottom layer. The top layer includes an array of metal sections that are electrically insulated from one another. The metal sections at a periphery of the array extend to a periphery of the multi-layer circuit board. The innermost metal sections in the array are electrically and thermally coupled to the bottom layer by vias formed through all of the top layer and any layers between the top layer and the bottom layer.

### BRIEF DESCRIPTION OF THE DRAWINGS

A more detailed understanding can be had from the following description, given by way of example in conjunction with the accompanying drawings wherein:

FIG. 1 is a top view of an example LED array;

FIG. 2A is a top view of an example top layer of an example multi-layer circuit board;

FIG. 2B is a top view of an example first additional layer of the example multi-layer circuit board of FIG. 2A;

FIG. 2C is a top view of an example second additional layer of the example multi-layer circuit board of FIGS. 2A and 2B;

FIG. 2D is a top view of an example bottom layer of the example multi-layer circuit

board of FIGS. 2A, 2B, 2C and 2D;

FIG. 3 is a cross-sectional view of the multi-layer circuit board of FIGS. 2A, 2B, 2C and 2D taken along the line a-a in FIG. 2A; and

FIG. 4 is a flow diagram of an example method of manufacturing a multi-layer circuit board, such as the multi-layer circuit board of FIGS. 2A, 2B, 2C, 2D and 3.

### DETAILED DESCRIPTION

Examples of different light illumination systems and/or light emitting diode (“LED”) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

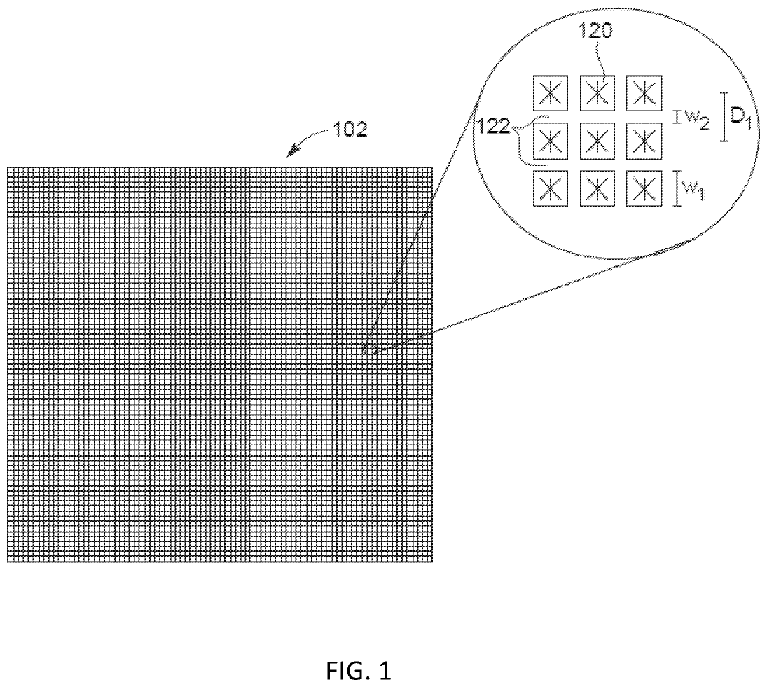

FIG. 1 is a top view of an example LED array 102. In the example illustrated in FIG. 1, the LED array 102 is an array of emitters 120. Emitters 120 in the LED array 102 may be individually addressable or may be addressable in groups/subsets.

An exploded view of a 3×3 portion of the LED array 102 is also shown in FIG. 1. As shown in the 3×3 portion exploded view, the LED array 102 may include emitters 120 that each have a width w₁. Lanes 122 between the emitters 120 may be a width, w₂, wide. The lanes 122 may provide an air gap between adjacent emitters or may contain other material. It will be understood that any widths and distances provided herein are examples only and that actual widths and/or dimensions may vary.

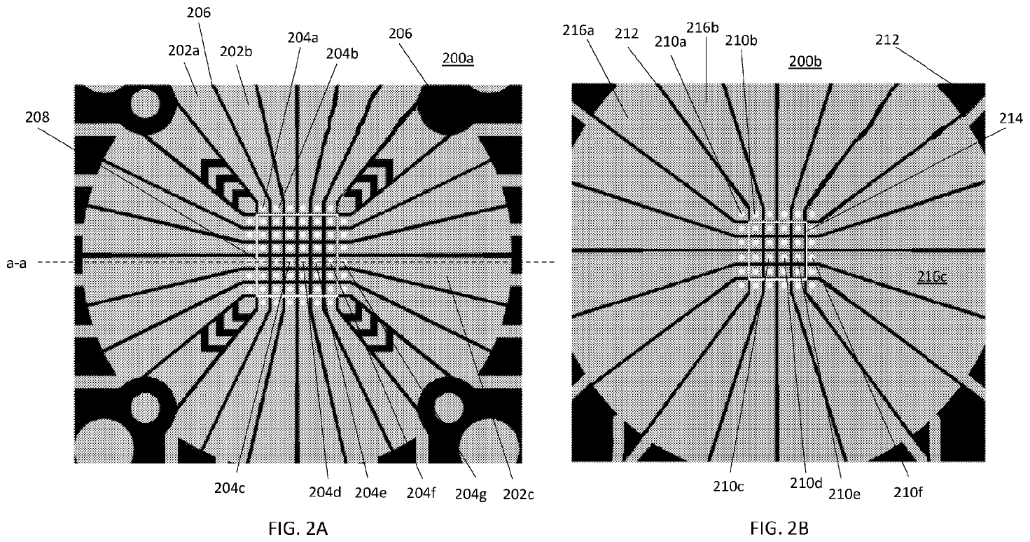

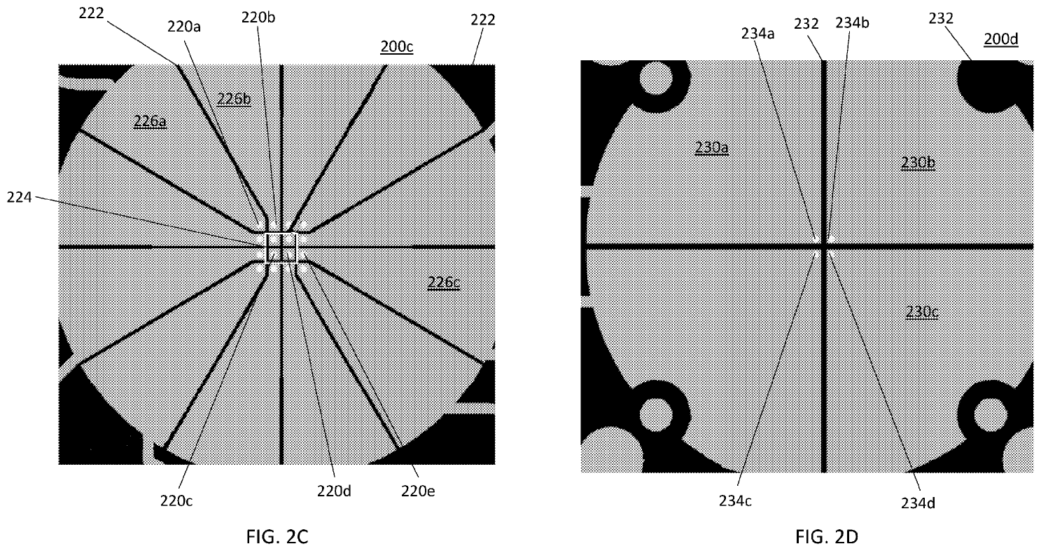

It will be understood that, although rectangular emitters arranged in a symmetric matrix are shown in FIG. 1, emitters of any shape and arrangement may be applied to the embodiments described herein. For example, the LED array 102 of FIG. 1 may include as many as, or even more than, 400 emitters in any applicable arrangement, such as a 7×7 matrix, a 20×20 matrix, a symmetric matrix, a non-symmetric matrix, or the like. It will also be understood that multiple sets of emitters, matrixes, and/or boards may be arranged in any applicable format to implement the embodiments described herein. In some embodiments, rows and columns may have differing numbers of emitters. One example of this is shown in FIG. 2A (described in detail below) where there is no emitter in each of the outer corners of the array. One of ordinary skill in the art will recognize that different arrangements of emitters may be used consistent with the embodiments described herein. In the embodiments described herein, it will be apparent that the number of layers in the multi-layer circuit board will dictate the number of emitters in the matrix, and vice versa. In other words, the number of layers that can be formed in the substrate may limit the number of emitters in the matrix, and/or the numbers of emitters in the matrix may dictate the number of layers that must be included in the circuit board.

A controller may be coupled to selectively power subgroups of emitters in an LED array. At least some of the emitters in the LED array may be individually controlled. In other embodiments, groups or subgroups of emitters may be controlled together. In some embodiments, the emitters may have distinct non-white colors. For example, at least four of the emitters may be RGBY groupings of emitters.

LED array luminaires may include light fixtures, which may be programmed to project different lighting patterns based on selective emitter activation and intensity control. Such luminaires may deliver multiple controllable beam patterns from a single lighting device using no moving parts. Typically, this is done by adjusting the brightness of individual LEDs in a 1D or 2D array. Optics, whether shared or individual, may optionally direct the light onto specific target areas. In some embodiments, the height of the LEDs, their supporting substrate and electrical traces, and associated micro-optics may be less than 5 millimeters, as low as 2 mm, and/or as large as 20 or 25 mm.

LED arrays, including LEDs, mini LEDs, and/or μLED arrays, may be used to selectively and adaptively illuminate buildings or areas for improved visual display or to reduce lighting costs. In addition, such LED arrays may be used to project media facades for decorative motion or video effects. In conjunction with tracking sensors and/or cameras, selective illumination of areas around pedestrians may be possible. Spectrally distinct emitters may be used to adjust the color temperature of lighting, as well as support wavelength specific horticultural illumination.

Street lighting is an important application that may greatly benefit from use of LED arrays. A single type of LED array may be used to mimic various street light types, allowing, for example, switching between a Type I linear street light and a Type IV semicircular street light by appropriate activation or deactivation of selected emitters. In addition, street lighting costs may be lowered by adjusting light beam intensity or distribution according to environmental conditions or time of use. For example, light intensity and area of distribution may be reduced when pedestrians are not present. If emitters are spectrally distinct, the color temperature of the light may be adjusted according to respective daylight, twilight, or night conditions.

LED arrays are also well suited for supporting applications requiring direct or projected displays. For example, warning, emergency, or informational signs may all be displayed or projected using LED arrays. This allows, for example, color changing or flashing exit signs to be projected. If an LED array includes a large number of emitters, textual or numerical information may be presented. Directional arrows or similar indicators may also be provided.

Vehicle headlamps are an LED array application that may require a large number of pixels and a high data refresh rate. Automotive headlights that actively illuminate only selected sections of a roadway may be used to reduce problems associated with glare or dazzling of oncoming drivers. Using infrared cameras as sensors, LED arrays may activate only those emitters needed to illuminate the roadway while deactivating emitters that may dazzle pedestrians or drivers of oncoming vehicles. In addition, off-road pedestrians, animals, or signs may be selectively illuminated to improve driver environmental awareness. If emitters are spectrally distinct, the color temperature of the light may be adjusted according to respective daylight, twilight, or night conditions. Some emitters may be used for optical wireless vehicle to vehicle communication.

One of the challenges for LED arrays larger than 2×2 is routing a circuit board, such as a printed circuit board (PCB), in order to make the LEDs individually addressable. Additionally, for many applications, such as spotlights, torches and mobile flash, the power density may be relatively high (e.g., 1-10 W/mm²). Thus, in addition to complex routing, for high power density applications, good thermal design may be needed in order to prevent overheating. Embodiments described herein provide for a multi-layer circuit board, such as a multi-layer PCB, that may address both the addressability/routing and thermal challenges.

FIG. 2A is a top view of an example top circuit board layer 200a of an example multi-layer circuit board. In the example illustrated in FIG. 2A, the top layer 200a includes multiple metal sections 202 (only 202a, 202b and 202c are labeled for readability). Each of the metal sections 202 may be separated from any adjacent metal sections 202 via an electrically insulating material 206. In some embodiments, the metal sections may be or include Copper or Copper alloys, and the insulating material may be epoxy.

As with the metal sections 202, only a few regions of the electrically insulating material 206 are labeled in FIG. 2A for readability. In FIG. 2A, the metal sections are arranged as an array of metal sections. In the example illustrated in FIG. 2A, a plurality of metal contacts 204 (only 204a, 204b, 204c, 204d, 204e, 204f and 204g are labeled for readability), are provided on the metal sections 202 and may be arranged such that a single metal contact 204 is provided on each one of the metal sections 202. As in the illustrated example, there may not be a contact on every metal section (e.g., the corners or certain other metal sections 202 may be left un-contacted) or there may a contact on every metal section, depending on design constraints. As shown in FIG. 2A, the array of metal sections 202 may include a group of metal sections around the periphery of the array. In FIG. 2A, such metal sections include metal sections 202a, 202b and 202c as well as all metal sections outside of box 208. Box 208 denotes another group of metal sections 202 that are contained within the periphery of the array of metal sections.

As can be seen in FIG. 2A, the metal sections 202 around the periphery of the array of metal sections extend to the periphery of the multi-layer circuit board (the outer edges of the layer shown in each of FIGS. 2A, 2B, 2C and 2D). In some embodiments, the metal sections around the periphery of the array of metal sections may increase in surface area as they extend outward toward the periphery of the multi-layer circuit board and have a maximum width at the periphery of the multi-layer circuit board. However, in some embodiments, the maximum width may be reached before the metal section reaches the end of the multi-layer circuit board and thinner or otherwise smaller regions of metal may be used to extend the thermal and electrical connection to the periphery of the multi-layer circuit board, as shown.

The metal sections may have a substantially triangular shape, as shown in FIGS. 2A, 2B, 2C and 2D, for example, to maximize the amount of metal that can be allotted to each LED. For example, in FIG. 2A, the top layer 200a includes 28 metal sections 202. Each of the metal sections is substantially triangular in shape, with a vertex angle of each of the metal sections pointed towards a center of the layer 200a. The vertex angle may be approximately equal to 360°/28 or approximately 13°. The section of the triangle opposite the vertex angle may be straight or, as shown in FIGS. 2A, 2B, 2C and 2D, slightly rounded such that all of the metal sections in a layer may form a circular shaped metal with individual sections separated from others by an insulating material. As can be seen in FIG. 2A, in some or all of the layers, the vertex angle may also slightly deviate in shape from a triangle to, for example, better make the connection to the individual LEDs, pads or vias. The vertex angles may also slightly deviate such that not all metal sections have exactly the same vertex angle in order to better make thermal or electrical connections or to provide a better fit within the circuit board. Slight angular variations and/or curvatures, such as one or more of those mentioned in this paragraph, are intended to fall within the scope of “substantially” triangle shaped.

While they cannot be seen in FIG. 2A, the top layer 200a may include one via through the circuit board layer 200a under each of the contacts 204 within the box 208. The terminating ends of each of the vias that extend through the top circuit board layer 200a are labeled in FIG. 2B as 210. The vias may be open or filled with a metal material, such as copper, such that the vias may establish an electrical and thermal coupling with a corresponding metal section in the circuit board layer below it. In some embodiments, the metal contacts 204 may be solder balls that are electrically coupled to the vias.

FIG. 2B is a top view of an example first additional circuit board layer 200b of the example multi-layer circuit board of FIG. 2A. Similar to FIG. 2A, the first additional circuit board layer 200b includes multiple metal sections 216 (only 216a, 216b and 216c are labeled for readability). Each of the metal sections 216 may be separated from any adjacent metal sections 216 via an electrically insulating material 212. As with the metal sections 216, only a few regions of the electrically insulating material 212 are labeled in FIG. 2B for readability.

As shown in FIG. 2B and similar to FIG. 2A, the array of metal sections 216 may include a group of metal sections around the periphery of the array. In FIG. 2B, such metal sections include metal sections 216a, 216b and 216c as well as all metal sections outside of box 214. Box 214 denotes another group of metal sections 216 that are contained within the periphery of the array of metal sections. As can be seen in FIG. 2B, similar to FIG. 2A, the metal sections 216 around the periphery of the array of metal sections extend to the periphery of the multi-layer circuit board (the outer edges of the layer shown in each of FIGS. 2A, 2B, 2C and 2D). In some embodiments, the metal sections around the periphery of the array of metal sections may increase in surface area as they extend outward toward the periphery of the multi-layer circuit board and have a maximum width at the periphery of the multi-layer circuit board. However, in some embodiments, the maximum width may be reached before the metal section reaches the end of the multi-layer circuit board and thinner or otherwise smaller regions of metal may be used to extend the thermal and electrical connection to the periphery of the multi-layer circuit board, as shown.

As mentioned above, the metal sections may have a substantially triangular shape, as shown in FIGS. 2A, 2B, 2C and 2D, for example, to maximize the amount of metal that can be allotted to each LED. For example, in FIG. 2B, the layer 200b includes 20 metal sections 216. Each of the metal sections is substantially triangular in shape, with a vertex angle of each of the metal sections pointed towards a center of the layer 200b. The vertex angle may be approximately equal to 360° /20 or approximately 18°. The section of the triangle opposite the vertex angle may be straight or, as shown in FIGS. 2A, 2B, 2C and 2D, slightly rounded such that all of the metal sections in a layer may form a circular shaped metal with individual sections separated from others by an insulating material. As can be seen in FIG. 2B, in some or all of the layers, the vertex angle may also slightly deviate in shape from a triangle to, for example, better make the connection to the individual LEDs, pads or vias. The vertex angles may also slightly deviate such that not all metal sections have exactly the same vertex angle in order to better make thermal or electrical connections or to provide a better fit within the circuit board. Slight angular variations and/or curvatures, such as one or more of those mentioned in this paragraph, are intended to fall within the scope of “substantially” triangle shaped.

While they cannot be seen in FIG. 2B, the first additional layer 200b may include one via through the circuit board layer 200b for each metal section 216 within the box 214. The terminating ends of each of the vias that extend through the top circuit board layer 200b are labeled in FIG. 2C as 220. The vias may be open or filled with a metal material, such as copper, such that the vias may establish an electrical and thermal coupling with a corresponding metal section in the circuit board layer below it. As can be seen in FIGS. 2A and 2B, no vias are formed under the metal contacts 204 around the periphery of the array of the metal contacts illustrated in FIG. 2A. This may or may not be permissible in different designs, however, depending on how electrical connections are made in the particular design.

FIG. 2C is a top view of an example second additional layer 200c of the example multi-layer circuit board of FIGS. 2A and 2B. Similar to FIGS. 2A and 2B, the second additional circuit board layer 200c includes multiple metal sections 226 (only 226a, 226b and 226c are labeled for readability). Each of the metal sections 226 may be separated from any adjacent metal sections 226 via an electrically insulating material 222. As with the metal sections 226, only a few regions of the electrically insulating material 222 are labeled in FIG. 2C for readability.

As shown in FIG. 2C and similar to FIGS. 2A and 2B, the array of metal sections 226 may include a group of metal sections around the periphery of the array. In FIG. 2C, such metal sections include metal sections 226a, 226b and 226c as well as all metal sections outside of box 224. Box 224 denotes another group of metal sections 226 that are contained within the periphery of the array of metal sections. As can be seen in FIG. 2C, similar to FIGS. 2A and 2B, the metal sections 226 around the periphery of the array of metal sections may extend to the periphery of the multi-layer circuit board (the outer edges of the layer shown in each of FIGS. 2A, 2B, 2C and 2D). In some embodiments, the metal sections around the periphery of the array of metal sections may increase in surface area as they extend outward toward the periphery of the multi-layer circuit board and have a maximum width at the periphery of the multi-layer circuit board. However, in some embodiments, the maximum width may be reached before the metal section reaches the end of the multi-layer circuit board and thinner or otherwise smaller regions of metal may be used to extend the thermal and electrical connection to the periphery of the multi-layer circuit board, as shown.

As mentioned above, the metal sections may have a substantially triangular shape, as shown in FIGS. 2A, 2B, 2C and 2D, for example, to maximize the amount of metal that can be allotted to each LED. For example, in FIG. 2C, the layer 200c includes 12 metal sections 226. Each of the metal sections is substantially triangular in shape, with a vertex angle of each of the metal sections pointed towards a center of the layer 200b. The vertex angle may be approximately equal to 360° /12 or approximately 30°. The section of the triangle opposite the vertex angle may be straight or, as shown in FIGS. 2A, 2B, 2C and 2D, slightly rounded such that all of the metal sections in a layer may form a circular shaped metal with individual sections separated from others by an insulating material. As can be seen in FIG. 2C, in some or all of the layers, the vertex angle may also slightly deviate in shape from a triangle to, for example, better make the connection to the individual LEDs, pads or vias. The vertex angles may also slightly deviate such that not all metal sections have exactly the same vertex angle in order to better make thermal or electrical connections or to provide a better fit within the circuit board. Slight angular variations and/or curvatures, such as one or more of those mentioned in this paragraph, are intended to fall within the scope of “substantially” triangle shaped.

While they cannot be seen in FIG. 2C, the second additional layer 200c may include one via through the circuit board layer 200c for each metal section 226 within the box 224. The terminating ends of each of the vias that extend through the second additional circuit board layer 200c are labeled in FIG. 2D as 234. The vias may be open or filled with a metal material, such as copper, such that the vias may establish an electrical and thermal coupling with a corresponding metal section in the circuit board layer below it. As can be seen in FIGS. 2B and 2C, no vias are formed through the first additional circuit board layer 200b around the periphery of the array of the metal sections illustrated in FIG. 2B.

FIG. 2D is a top view of an example bottom layer 200d of the example multi-layer circuit board of FIGS. 2A, 2B, 2C and 2D. Similar to FIGS. 2A, 2B and 2C, the bottom circuit board layer 200d includes multiple metal sections 230 (only 230a, 230b and 230c are labeled for readability). Each of the metal sections 230 may be separated from any adjacent metal sections 230 via an electrically insulating material 232. As with the metal sections 230, only a few regions of the electrically insulating material 232 are labeled in FIG. 2D for readability.

As shown in FIG. 2D, since layer 200d is the bottom layer of the multi-layer circuit board, the layer 200d only includes four metal sections and only shows four terminating ends of vias 234a, 234b, 234c and 234d from the layer above (the second additional layer 200c illustrated in FIG. 2C). The metal sections 230 are similar to the metal sections around the periphery of the array of metal sections for each of FIGS. 2A, 2B and 2C (the three layers above the bottom layer 2D) and, in some embodiments, may increase in surface area as they extend outward toward the periphery of the multi-layer circuit board and have a maximum width at the periphery of the multi-layer circuit board. However, in some embodiments, the maximum width may be reached before the metal section reaches the end of the multi-layer circuit board and thinner or otherwise smaller regions of metal may be used to extend the thermal and electrical connection to the periphery of the multi-layer circuit board, as shown. As can be seen in FIGS. 2C and 2D, no vias are formed through the circuit board layer 200c in metal sections 226 around the periphery of the array of metal sections 226. Additionally, while not shown in the Figures, there may be no vias formed through the bottom layer 200d.

As mentioned above, the metal sections may have a substantially triangular shape, as shown in FIGS. 2A, 2B, 2C and 2D, for example, to maximize the amount of metal that can be allotted to each LED. For example, in FIG. 2D, the bottom layer 200d includes 4 metal sections 230. Each of the metal sections is substantially triangular in shape, with a vertex angle of each of the metal sections pointed towards a center of the layer 200d. The vertex angle may be approximately equal to 360°/4 or approximately 90°. The section of the triangle opposite the vertex angle may be straight or, as shown in FIGS. 2A, 2B, 2C and 2D, slightly rounded such that all of the metal sections in a layer may form a circular shaped metal with individual sections separated from others by an insulating material. Slight angular variations and/or curvatures, such as one or more of those mentioned herein, are intended to fall within the scope of “substantially” triangle shaped.

While not shown in FIGS. 2A, 2B, 2C and 2D, an LED array may be mounted to the multi-layer circuit board via the contacts 204 on the top layer 200a. Accordingly, given the structure of the multi-layer circuit board described above with respect to FIGS. 2A, 2B, 2C and 2D, each connected emitter in the LED array mounted on the top layer 200a may have one dedicated metal section for optimal heat spreading. In other words, in the top layer 200a, each of the emitters outside of the box 208 around the periphery of the array may have a dedicated metal section in the top layer 200A that has a relatively large surface area. Moving from the periphery of the LED array towards the middle, the next grouping of emitters may have a dedicated metal section in the first additional layer 200B that has a relatively large surface area. Continuing to move towards the middle of the LED array, each next grouping of emitters may have a dedicated metal section in the layer below. In the illustrated example, the next grouping of emitters may have a dedicated metal section in the second additional layer 200C that has a relatively large surface area. Each of the innermost emitters in the LED array may have a dedicated metal section in the bottom layer 200D.

This may provide for extremely efficient and effective heat dissipation for a large array of LEDs. In particular, routing some of the LEDs to lower layers where they can be thermally coupled to individual, large surface area metal sections, may effectively provide individual heat sinking for each emitter in an array. Further, because each deeper layer is coupled to fewer emitters than the layer above it, the metal sections can be made to have larger surface areas moving deeper into the multi-layer circuit board structure. This may enable the structure to compensate for added thermal resistance of the via and may enable the surface area of the metal sections to be maximized without violating the electrical rules. Additionally, as shown in the Figures, to optimize thermal design, each LED should be able to reach as much metal (e.g., PCB copper) as possible. In the illustrated examples, this is accomplished using a triangle metal or copper shape per LED, which may result in a circular star like pattern, as shown in the Figures, although one of ordinary skill in the art will understand that the basic shape can be modified consistent with the descriptions herein.

While four layers are shown in FIGS. 2A, 2B, 2C and 2D, a multi-layer circuit board may include any number of different layers consistent with the embodiments described herein. However, the amount of layers may be defined by the size of the LED array to be mounted on the circuit board. For example, for an array of N×N emitters, the multi-layer circuit board may have at least N/2+1 layers. For asymmetric light sources of size N×M, the multi-layer circuit board may be defined by the smallest dimension. For example, if M<N, then the multi-layer circuit board may have at least M/2+1 layers.

While this arrangement may provide excellent heat dissipation, it may also enable a relatively simple routing of the electrical connections for the LED array. For example, if a square 7×7 LED matrix is used as a light source, a multi-layer PCB, such as described above with respect to FIGS. 2A, 2B, 2C and 2D and further below, may be used to make the electrical connections for the emitters as well. For example, a square 7×7 matrix may need 4 layers to make the required electrical connections while a 5×7 matrix may need 3 layers. The most outside circle, square or rectangle, for example, may be contacted at the top layer, the next internal LED circle, square or rectangle, for example, may be contacted using vias to the next lower PCB layer. This layer may also pass the contacts needed for the inner LED circle, square or rectangle, for example, to the layers below. This process may be repeated until the center emitter(s) is/are reached. The general shape and pattern of the metal sections may be similar in each layer to maximize the amount of metal that can be dedicated to each emitter.

Although not shown in the drawings, a heat sink, either individual or incorporated into another circuit board, such as a control board, may be located adjacent the bottom layer 200d of the multi-layer circuit board. In some embodiments, the multi-layer PCB may be mounted on or over the heat sink with and may include intervening thermal or other layers, for example to prevent shorting.

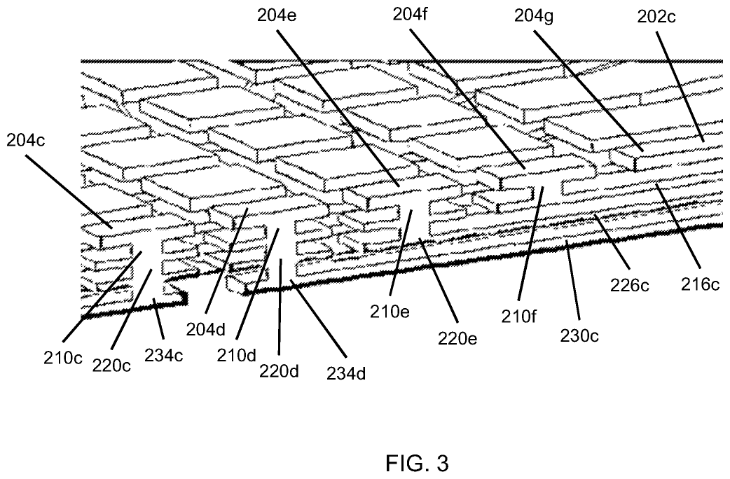

FIG. 3 is a cross-sectional view of the multi-layer circuit board of FIGS. 2A, 2B, 2C and 2D taken along the line a-a in FIG. 2A. As can be seen in FIG. 2A, line a-a cuts through an entire row of emitters in the illustrated LED array in one of the two innermost rows of LEDs in the array. In the illustrated example, the two innermost emitters in the row, those electrically coupled to contacts 204c and 204d, are electrically and thermally contacted using vias 210d, 220d and 234d and 210c, 220c and 234c, respectively, routing them thermally and electrically to metal sections of the bottom layer (only metal layer 230c is labeled in FIG. 3). Heading toward the right in FIG. 3, the next innermost emitter in the row, that electrically coupled to contact 204e, is electrically and thermally contacted using vias 210e and 220e, routing it thermally and electrically to the layer above the bottom layer (also referred to as metal section 226c). Heading further toward the right in FIG. 3, the next innermost emitter in the row, that electrically coupled to contact 204f, is electrically and thermally contacted using via 210f, routing it thermally and electrically to the layer below it (also referred to as metal section 216c). Finally, the outermost emitter in the row, that electrically coupled to contact 204g, is directly mounted to metal section 202c of the top layer of the multi-layer circuit board.

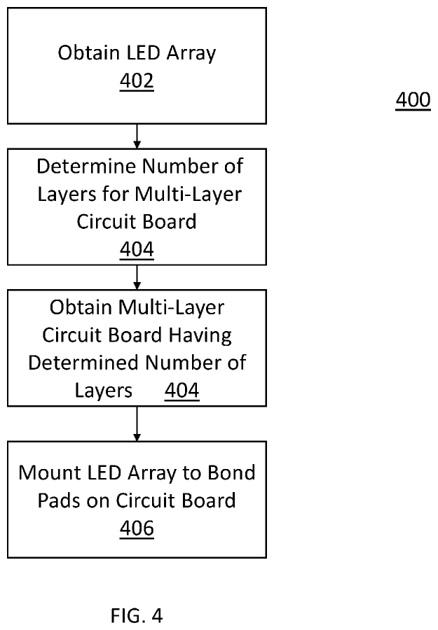

FIG. 4 is a flow diagram of an example method 400 of manufacturing a multi-layer circuit board, such as the multi-layer circuit board of FIGS. 2A, 2B, 2C, 2D and 3. In the example illustrated in FIG. 4, the method includes obtaining an LED array (402). The obtaining may include manufacturing the LED array or otherwise obtaining it completely or partially manufactured. A number of layers for a multi-layer circuit board may be determined (404). In some embodiments, this may be done by setting the number of layers equal to or greater than N/2+1. N may be the number of rows in the array of LEDs. Where the array is not square, N may be equal to the number of LEDs in the smaller of the two dimensions.

A multi-layer circuit board may be obtained that has the determined number of layers (406). The multi-layer circuit board may have some or all of the features of the multi-layer circuit board described above with respect to FIGS. 2A, 2B, 2C, 2D and 3. For example, the multi-layer circuit board may include at least a top layer, a bottom layer and at least one additional layer between the top layer and the bottom layer. The top layer may include an array of metal sections that are electrically insulated from one another. The metal sections at a periphery of the array may extend to a periphery of the multi-layer circuit board. Each of the innermost metal sections in the array may be electrically and thermally coupled to the bottom layer by vias formed through all of the top layer and the at least one additional layer between the top layer and the bottom layer. A bond pad may be disposed on each of the metal sections. In some embodiments, the obtaining the multi-layer circuit board may include manufacturing it, such as by forming at least the top layer and the bottom layer and forming the bond pad on each of the metal sections of the top layer. In such case, the manufacturing may include providing an insulating material between each of the metal sections. In some embodiments, the obtaining may include obtaining it completely or partially manufactured and/or providing the specifications for the multi-layer circuit board for such manufacturing.

The array of LEDs may be mounted to the bond pads (408). In some embodiments, the method may include forming a heat sink under the bottom layer. In some embodiments, each of the top layer and the at least one additional layer may include an array of metal sections with a group of the metal sections around the periphery of the array extending to the periphery of the multi-layer board and a group metal sections contained within the periphery of the array electrically and thermally coupled to at least one of the integer number of layers below it. In some embodiments, for each of the bottom layer and the at least one additional layer, each of the metal sections in the group around the periphery of the array has a larger surface area than each of the metal sections in the group around the periphery of the array of the layer above it.

Having described the embodiments in detail, those skilled in the art will appreciate that, given the present description, modifications may be made to the embodiments described herein without departing from the spirit of the inventive concept. Therefore, it is not intended that the scope of the invention be limited to the specific embodiments illustrated and described.

1. A multi-layer circuit board comprising:
a bottom layer;
a top layer comprising an array of metal sections that are electrically insulated from one another, a plurality of the metal sections at a periphery of the array extending to a periphery of the multi-layer circuit board;
at least one additional layer between the bottom layer and the top layer; and
a plurality of vias each extending through all of the top layer and the at least one additional layer between the top layer and the bottom layer and electrically and thermally coupling innermost metal sections of the metal sections in the array to the bottom layer.

2. The multi-layer circuit board of claim 1, wherein the multi-layer circuit board comprises an integer number of layers, including the top layer, the bottom layer, and all of the at least one additional layer between the top layer and the bottom layer, that equals at least N/2+1, wherein N equals a number of the metal sections in the top layer.

3. The multi-layer circuit board of claim 2, wherein the at least one additional layer comprises an additional array of metal sections.

4. The multi-layer circuit board of claim 3, wherein, for the top layer and the at least one additional layer between the top layer and the bottom layer, a group of the metal sections around the periphery of the array extend to the periphery of the multi-layer board, and a group of the metal sections contained within the periphery of the array are electrically and thermally coupled to at least one of the layers below it.

5. The multi-layer circuit board of claim 4, wherein, for the bottom layer and the at least one additional layer, each of the metal sections in the group of the metal sections around the periphery of the array has a larger surface area than each of the metal sections in the group around the periphery of the array of the layer above it.

6. The multi-layer circuit board of claim 1, further comprising an insulating material between each of the metal sections in the array.

7. A multi-layer circuit board comprising:
a first circuit board layer comprising:
a first array of first metal sections comprising an outer group of the first metal sections arranged around a periphery of the first array and an inner group of the first metal sections contained within the periphery of the first array, each of the first metal sections in the first array being electrically insulated from each of the other first metal sections in the first array, and each of the first metal sections in the outer group extending to an outer periphery of the first circuit board layer, and
a plurality of first vias formed through the first circuit board layer, each of the plurality of first vias being disposed under the inner group of the first metal sections and containing metal; and
a second circuit board layer comprising a second array of second metal sections,
the first circuit board layer being adjacent the second circuit board layer with the first metal sections in the inner group being electrically and thermally coupled to one of the second metal sections of the second circuit board layer via the plurality of first vias.

8. The multi-layer circuit board of claim 7, further comprising an array of bond pads, each of the bond pads in the array disposed on a respective one of the first metal sections.

9. The multi-layer circuit board of claim 8, further comprising an array of light-emitting diodes (LEDs) coupled to the array of bond pads.

10. The multi-layer circuit board of claim 7, wherein:
the second metal sections of the second circuit board layer comprise an outer group arranged around a periphery of the second array and an inner group contained within the periphery of the second array,
the second circuit board layer further comprises a plurality of second vias formed through the second circuit board layer, each of the plurality of second vias being disposed under the inner group of the second metal sections and containing metal,
the circuit board further comprises a third circuit board layer comprising a third array of third metal sections, and
the second circuit board layer is adjacent the third circuit board layer with the second metal sections in the inner group being electrically and thermally coupled to one of the third metal sections of the third circuit board layer via the plurality of second vias.

11. The multi-layer circuit board of claim 10, further comprising at least one other circuit board layer adjacent the third circuit board layer, the at least one other circuit board layer comprising an other array of a plurality of other metal sections comprising an outer group arranged around a periphery of the other array and an inner group contained within the periphery of the other array and being electrically and thermally coupled to the third circuit board layer or the one of the at least one other circuit board layer above it via the inner group.

12. The multi-layer circuit board of claim 10, wherein the second metal sections have a smaller surface area than the third metal sections, and the first metal sections have a smaller surface area than the second metal sections.

13. The multi-layer circuit board of claim 12, wherein each of the first metal sections and the second metal sections have a substantially triangular shape with a vertex angle equal to 360°/N, wherein N is a number of metal sections in the layer.

14. The multi-layer circuit board of claim 7, further comprising a heat sink adjacent a lowermost circuit board layer of the multi-layer circuit board.

15. A method of manufacturing a light-emitting diode (LED) device, the method comprising:
obtaining an array of LEDs;
determining a number of layers for a multi-layer circuit board greater than or equal to N/2+1, wherein N is an integer number greater than one of the LEDs in the array of LEDs;
obtaining a multi-layer circuit board that comprises at least a top layer, a bottom layer and at least one additional layer between the top layer and the bottom layer, the top layer comprising an array of metal sections that are electrically insulated from one another, the metal sections at a periphery of the array extending to a periphery of the multi-layer circuit board, each of the innermost metal sections in the array being electrically and thermally coupled to the bottom layer by vias formed through all of the top layer and the at least one additional layer between the top layer and the bottom layer, and a bond pad being disposed on each of the metal sections; and
mounting the array of LEDs to the bond pads.

16. The method of claim 15, wherein the obtaining the multi-layer circuit board comprises manufacturing the multi-layer circuit board by forming at least the top layer and the bottom layer and forming the bond pad on each of the metal sections of the top layer.

17. The method of claim 16, wherein the manufacturing the multi-layer circuit board comprises providing an insulating material between each of the metal sections

18. The method of claim 15, further comprising forming a heat sink under the bottom layer.

19. The method of claim 15, wherein each of the top layer and the at least one additional layer comprises an array of metal sections with a group of the metal sections around the periphery of the array extending to the periphery of the multi-layer board and a group metal sections contained within the periphery of the array electrically and thermally coupled to at least one of the integer number of layers below it.

20. The method of claim 19, wherein, for each of the bottom layer and the at least one additional layer, each of the metal sections in the group around the periphery of the array has a larger surface area than each of the metal sections in the group around the periphery of the array of the layer above it.
